(19) United States
(12) Patent Application Publication
(10) Pub. No.: US 2026/0011999 A1
(43) Pub. Date: Jan. 8, 2026

(54) VEHICLE CUTOFF DEVICE

(71) Applicants: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(72) Inventors: Koki UCHIDA, Yokkaichi-Shi, Mie (JP); Takafumi KAWAKAMI, Yokkaichi-Shi, Mie (JP)

(73) Assignees: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(21) Appl. No.: 18/992,465

(22) PCT Filed: Jul. 12, 2022
(86) PCT No.: PCT/JP2022/027379

§ 371 Date: Jan. 8, 2025

(51) Int. Cl. H02H 3/04; G01R 31/327; H02H 3/08

(52) U.S. Cl. CPC H02H 3/044; G01R 31/327; H02H 3/08

(57) ABSTRACT

Provided is a vehicle cutoff device that allows a switch to be operated in a form in which the durability performance thereof is enhanced. A cutoff device includes a first switch configured to switch a power path between a conductive state and a cutoff state, the power path serving as a path to transmit power derived from a power supply unit. The cutoff device includes a control unit configured to execute degradation determination processing in which a resistance value and a resistance threshold of the first switch are compared. The control unit determines that the first switch is in a degraded state when the resistance value is greater than or equal to the resistance threshold, and notifies an external entity of the degraded state.

### CROSS-REFERENCE TO RELATED APPLICATIONS

This application is the U.S. national stage of PCT/JP2022/027379 filed on Jul. 12, 2022, the contents of which is incorporated herein.

### TECHNICAL FIELD

The present disclosure relates to a vehicle cutoff device.

### BACKGROUND

JP 2017-188983A discloses a power supply device that supplies power stored in a battery to a load by executing an on/off control of a semiconductor switch by a semiconductor switch drive unit.

With an increase in the output of a power supply, the value of current flowing through a power path extending from the power supply to a load will increase. Also, the burden on a switch or a circuit breaker intervening on the power path may increase, resulting in concern that the contact of the switch or the circuit breaker is susceptible to wear. Accordingly, there is an increased need to determine whether the wear of the contact of the switch or the circuit breaker has advanced, and to operate the switch or the circuit breaker based on the result of the determination. As an example, a method is known in which the upper limit of the number of times of opening/closing of the switch or the circuit breaker is set in advance, and whether the switch or the circuit breaker satisfies the required performance is determined by comparing the number of times of opening/closing of the switch or the circuit breaker with the upper limit. However, with this method, there may be a situation where it is determined that the switch or the circuit breaker no longer satisfies the required performance when the number of times of opening/closing reaches the upper limit even though the wear of the contact of the switch or the circuit breaker has not advanced and the required performance is satisfied (i.e., is in a usable state). For this reason, there is a need for a method for operating a switch or a circuit breaker after enhancing the durability performance thereof.

The present disclosure has been made in view of the above-described circumstances, and an object thereof is to provide a vehicle cutoff device that allows a switch to be operated in a form in which the durability performance thereof is enhanced.

### SUMMARY

A vehicle cutoff device according to the present disclosure is a vehicle cutoff device including a switch configured to switch a power path between a conductive state and a cutoff state, the power path serving as a path to transmit power derived from a power supply unit, wherein the cutoff device includes a control unit configured to execute degradation determination processing in which a resistance value and a resistance threshold of the switch are compared, the control unit determines that the switch is in a degraded state if the resistance value is greater than or equal to the resistance threshold, and notifies an external entity of the degraded state.

### Advantageous Effects

According to the present disclosure, a switch can be operated in a form in which the durability performance is enhanced.

### BRIEF DESCRIPTION OF DRAWINGS

FIG. 1 is a circuit diagram illustrating a vehicle power supply system including a vehicle cutoff device according to Embodiment 1.

FIG. 2 is a flowchart showing an example of control executed by a control unit of the vehicle cutoff device according to Embodiment 1.

FIG. 3 is a graph showing temporal changes of the resistance value of a first switch.

FIG. 4 is a circuit diagram showing positions at which a voltage detection unit is connected to a low-potential side power path according to another embodiment.

### DETAILED DESCRIPTION OF PREFERRED EMBODIMENTS

First, aspects of the present disclosure will be listed and described.

In a first aspect, a vehicle cutoff device according to the present disclosure is a vehicle cutoff device including a switch configured to switch a power path between a conductive state and a cutoff state, the power path serving as a path to transmit power derived from a power supply unit. The cutoff device includes a control unit configured to execute degradation determination processing in which a resistance value and a resistance threshold of the switch are compared. The control unit determines that the switch is in a degraded state if the resistance value is greater than or equal to the resistance threshold, and notifies an external entity of the degraded state.

The vehicle cutoff device according to the first aspect may use the resistance value of the switch as an indicator for estimating the state of the switch. This makes it possible to determine whether or not the switch is in the degraded state, in a form suitable for the switch itself, thus easily enhancing the durability performance of the switch. Furthermore, this configuration notifies an external entity of the degraded state, and therefore the external entity can easily take measures suitable for the state of the switch. Here, the degraded state refers to a state in which the switch has deteriorated as compared with the state thereof when initially provided in the cutoff device, and the performance thereof in switching the power path between the conductive state and the cutoff state has been reduced.

In a second aspect, in the vehicle cutoff device according to the first aspect, the resistance value may be based on a potential difference between two sides of the switch when the switch is in an ON state and current flows through the power path, and on the current flowing through the power path.

The vehicle cutoff device according to the second aspect is configured to determine that the switch is in the degraded state if the resistance value that is based on the potential difference between two sides of the switch when the switch is in the ON state and current flows through the power path, and on the current flowing through the power path is greater than or equal to the threshold. This makes it possible to determine whether the switch is in the degraded state, in a form suitable for the state of the switch itself, and therefore the switch can be operated in a form in which the durability performance thereof is enhanced.

In a third aspect, the vehicle cutoff device according to the second aspect may further include a second switch configured to switch the power path between the conductive state and the cutoff state. Start of energization or current increase of the power path may occur as a result of execution of a switching control in which the switch is switched from an OFF state to the ON state after the second switch. The control unit may execute the degradation determination processing in which the resistance value when the switching control is executed is compared with the resistance threshold.

In the vehicle cutoff device according to the third aspect, in the switching control, the switch is switched to the ON state after the second switch, and therefore an inrush current is likely to flow through the switch. Accordingly, the contact of the switch is susceptible to wear (degradation). With this configuration, the degradation of the switch can be determined in the switching control in which the contact of the switch is susceptible to wear.

In a fourth aspect, in the vehicle cutoff device according to the third aspect, the power path may include a high-potential side power path, and a low-potential side power path having a lower potential than the high-potential side power path. The second switch may be provided on one of the high-potential side power path and the low-potential side power path, and the switch may be provided on the other of the high-potential side power path and the low-potential side power path. The cutoff device may further include a resistor, and a third switch connected in series to the resistor, and includes a parallel switching path on which the resistor and the third switch are connected in parallel to the switch. The switching control may be a control in which energization of the power path is started by bringing the second switch and the third switch into the ON state while the switch is in the OFF state, and the switch is thereafter switched to the ON state while the second switch is maintained in the ON state.

In the vehicle cutoff device according to the fourth aspect, by energizing the power path in advance by bringing the second switch and the third switch into the ON state, it is possible to cause current to flow through the power path while suppressing an excessive increase in the peak of the current flowing through the third switch by the resistor. Thereafter, the switch is switched to the ON state while the second switch and the third switch are maintained in the ON state. Accordingly, it is possible to suppress the peak of the inrush current flowing through the switch.

In a fifth aspect, in the vehicle cutoff device according to the fourth aspect, the control unit may detect a voltage between two terminals of the switch.

With the vehicle cutoff device according to the fifth aspect, it is possible to more accurately detect the resistance value of the switch of interest.

In a second aspect, in the vehicle cutoff device according to any one of the second through the fifth aspects, the control unit may execute the degradation determination processing in which the resistance value when a magnitude of the current flowing through the power path is greater than or equal to a current threshold is compared with the resistance threshold.

The vehicle cutoff device according to the sixth aspect is configured to compare the current flowing through the power path with the current threshold, and it is therefore possible, for example, to narrow down the states of the current used for detecting the resistance value to a state suitable for detection of the resistance value, thus increasing the credibility of the calculated resistance value.

### Embodiment 1

### Configuration of Cutoff Device

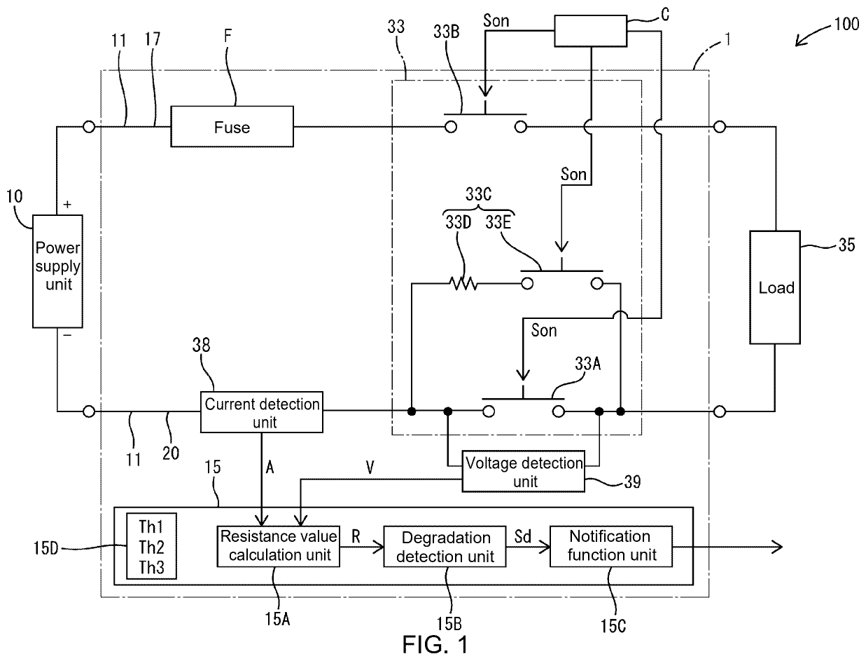

A vehicle power supply system 100 as shown in FIG. 1 is a power supply system configured to be mounted in a vehicle, and includes a power supply unit 10 and a cutoff device 1. The cutoff device 1 includes a power path 11, a system main relay 33, a current detection unit 38, a voltage detection unit 39, and a control unit 15. The vehicle power supply system 100 has a configuration in which power can be supplied from the power supply unit 10 to a load 35 via the power path 11 serving as a path through which power is transmitted between the power supply unit 10 and the load 35.

The power supply unit 10 is a battery capable of supplying power to the load 35. For example, as the power supply unit 10, it is possible to use, for example, an assembled battery or the like formed by a plurality of cells, such as lead-acid batteries, lithium ion batteries, nickel-metal hydride batteries, or the like that are combined in series.

The power path 11 includes a high-potential side power path 17 and a low-potential side power path 20. The high-potential side power path 17 is electrically connected to a high-potential side terminal of the power supply unit 10. The output voltage of the power supply unit 10 is applied to the high-potential side power path 17. The low-potential side power path 20 is electrically connected to a low-potential side terminal of the power supply unit 10. The low-potential side power path 20 has a lower potential than the high-potential side power path 17. The output voltage of the power supply unit 10 corresponds to the potential difference between the high potential side terminal and the low-potential side terminal. The power path 11 is a path to transmit power derived from the power supply unit 10 to the load 35. A fuse F is provided intervening on the high-potential side power path 17. The fuse F de-energizes the high-potential side power path 17 when excess current flows through the high potential side power path 17.

In the present disclosure, “electrically connected” preferably refers to a configuration in which objects to be connected are connected in a state in which the objects are conductively connected (a state in which current can flow therethrough) such that the potentials of the two objects are equal. However, the present disclosure is not limited to this configuration. For example, “electrically connected” may refer to a configuration in which objects to be connected are connected in a state in which the objects can be conductively connected while an electric component is interposed between the two objects.

The load 35 is electrically connected to the high-potential side power path 17 and the low-potential side power path 20. The load 35 is an in-vehicle electronic component, and products such as an electromotive component, an ECU, and an ADAS target component are applicable. Current that has been output from the high-potential side terminal of the power supply unit 10 flows through the high-potential side power path 17, the load 35, the low-potential side power path 20, and the low-potential side terminal of the power supply unit 10 in this order.

The system main relay 33 is provided intervening on the high-potential side power path 17 and the low-potential side power path 20, each of which is located between the power supply unit 10 and the load 35. The system main relay 33 includes a first switch 33A, a second switch 33B, and a parallel switching path 33C serving as a switch. Each of the first switch 33A and the second switch 33B is a relay switch having therein a contact that is physically switched between, for example, a state in which they are in contact with each other, and a state in which they are spaced apart from each other. The parallel switching path 33C includes a resistor 33D, and a third switch 33E connected in series to the resistor 33D. The third switch 33E is a relay switch having the same configuration as that of the first switch 33A and the second switch 33B. The third switch 33E is a so-called pre-charge relay.

The first switch 33A is provided on the low-potential side power path 20. The second switch 33B is provided on the high-potential side power path 17 located opposite to the power supply unit 10 with the fuse F interposed therebetween. The resistor 33D and the third switch 33E of the parallel switching path 33C are electrically connected to the low-potential side power path 20 so as to be in parallel with respect to the first switch 33A. The first switch 33A, the second switch 33B, and the third switch 33E are controlled by a predetermined control device C (hereinafter also referred to as a control device C) so as to be switched between an ON state and an OFF state. The first switch 33A, the second switch 33B, and the third switch 33E switch the power path 11 between a conductive state and a cutoff state by being switched between the ON state and the OFF state.

The current detection unit 38 is provided intervening on the low-potential side power path 20 located closer to the power supply unit 10 side than the first switch 33A is. The current detection unit 38 includes, for example, a resistor and a differential amplifier, and is configured to be capable of outputting, as a current value A, a value (specifically, an analog voltage corresponding to a value of current flowing through the low-potential side power path 20) indicating current flowing through the low-potential side power path 20. That is, the current detection unit 38 detects, as the current value A, the state of current flowing through the power path 11.

The voltage detection unit 39 is formed as, for example, a voltage detection circuit, and is configured to be capable of outputting a voltage value V corresponding to a potential difference between a terminal of the first switch 33A on the power supply unit 10 side and a terminal thereof on the load 35 side. That is, the voltage detection unit 39 detects the voltage state of the voltage of the power path 11 as the voltage value V. In other words, the voltage detection unit 39 detects, as the voltage value V, the potential difference between the terminals on two sides, namely, the power supply unit 10 side and the load 35 side, of the first switch 33A (the terminals on two sides, namely, a side on which power is supplied to the first switch 33A and a side on which power is output therefrom).

The control unit 15 is formed as, for example, a microcomputer, and includes a storage unit 15D composed of a CPU, a ROM, a RAM, and a nonvolatile memory or the like. The control unit 15 includes a resistance value calculation unit 15A, a degradation detection unit 15B, and a notification function unit 15C. The resistance value calculation unit 15A is configured to receive inputs of the current value A and the voltage value V from the current detection unit 38 and the voltage detection unit 39, respectively, and calculates and detects a resistance value R based on these values. For example, the resistance value R is obtained by dividing the voltage value V by the current value A. Based on the voltage value V from the voltage detection unit 39, the control unit 15 detects the voltage between the two terminals of the first switch 33A.

The degradation detection unit 15B is configured to be capable of executing degradation determination processing in which the resistance value R calculated by the resistance value calculation unit 15A is compared with a resistance threshold Th1 stored in the storage unit 15D of the control unit 15. The degradation detection unit 15B is configured to be capable of outputting a degradation signal Sd if it is determined, in the degradation determination processing, that the resistance value R is greater than or equal to the resistance threshold Th1. The degradation signal Sd is output when the first switch 33A is in a degraded state. That is, when the resistance value R is greater than or equal to the resistance threshold Th1, the control unit 15 determines that the first switch 33A is in the degraded state. If it is determined, in the degradation determination processing, that the magnitude of the resistance value R is smaller than the resistance threshold Th1, the degradation detection unit 15B does not output the degradation signal Sd. In this case, the control unit 15 determines that the first switch 33A is not in the degraded state.

The notification function unit 15C is formed by, for example, a communication device, and is configured to perform notification by information transmission to an external device (not shown) such as a battery management system (BMS), based on the degradation signal Sd being input from the degradation detection unit 15B.

### Control in Control Unit

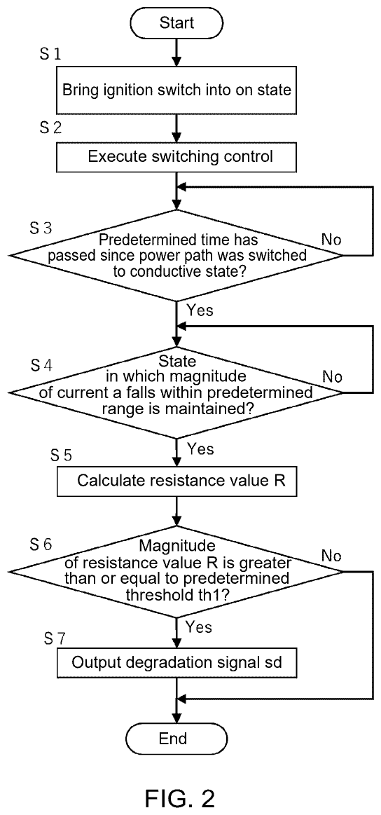

Next, an example of control executed by the control unit 15 will be described with reference to FIG. 2 and so forth. For example, when an ignition switch is off in a vehicle in which the vehicle power supply system 100 is mounted, the OFF state is maintained for the first switch 33A and the second switch 33B of the system main relay 33, and the third switch 33E of the parallel switching path 33C. At this time, the power path 11 is in a cutoff state in which the supply of power from the power supply unit 10 to the load 35 is cutoff.

From this state, first, step S1 is executed, thus switching the ignition switch from OFF to ON. Next, when the processing proceeds to step S2, an ON signal Son (see FIG. 1) is output from the control device C, and a switching control in which the first switch 33A, the second switch 33B, and the third switch 33E are switched from the OFF state to an ON state is executed based on the ON signal Son. Specifically, in the switching control, the second switch 33B, the third switch 33E, and the first switch 33A are switched in this order from the OFF state to the ON state, based on the ON signal Son output from the control device C. In other words, the switching control is a control in which energization of the power path 11 is started by bringing the second switch 33B and the third switch 33E into the ON state while the first switch 33A is in the OFF state, and thereafter the first switch 33A is switched to the ON state while maintaining the second switch 33B and the third switch 33E in the ON state. That is, the first switch 33A is switched from the OFF state to the ON state after the second switch 33B. Note that the timing at which the ON signal Son is output from the control device C to each switch can be changed in various manners. That is, the control device C is capable of executing a control different from the switching control.

For example, the timing at which the second switch 33B, the third switch 33E, and the first switch 33A are switched to the ON state can be staggered by staggering the timing at which the ON signal Son is output from the control device C to each of the second switch 33B, the third switch 33E, and the first switch 33A. Note that the power path 11 starts energization when the second switch 33B and the third switch 33E have been switched to the ON state. Since the resistor 33D is connected in series to the third switch 33E, current starts to flow through the power path 11 such that the magnitude thereof gradually increases.

Furthermore, when the first switch 33A is switched to the ON state, the power path 11 enters a conductive state in which the supply of power from the power supply unit 10 to the load 35 is allowed. When the first switch 33A is switched to the ON state, an inrush current immediately flows through the first switch 33A. At this time, current increase in which the current value A flowing through the power path 11 is rapidly increased occurs. In this manner, start of energization or current increase of the power path 11 occurs as a result of execution of the switching control. The inrush current continues to flow for a predetermined short time after the first switch 33A has been switched to the ON state. After the predetermined short time has passed, the current flowing through the first switch 33A is stabilized so as to remain in a predetermined range that is smaller than the magnitude of the inrush current. In this manner, the first switch 33A is switched to the ON state, and current flows through the power path 11.

Then, when the processing proceeds to step S3, the control unit 15 determines whether the predetermined short time has passed since the power path 11 was switched to the conductive state (since the first switch 33A was switched from the ON state). For example, the control unit 15 is provided with a timer function, and is configured to be capable of measuring the predetermined short time since the power path 11 has been switched to the conductive state. The fact that the power path 11 has been switched to the conductive state can be determined based on, for example, the degree to which the current value A changes within a predetermined time (the amount of change per unit time of the current value A). In step S3, if the control unit 15 determines that the predetermined short time has not passed since the power path 11 was switched to the conductive state (No in step S3), the processing of step S3 is repeated.

Then, in step S3, if the control unit 15 determines that the predetermined short time has passed since the power path 11 was switched to the conductive state (Yes in step S3), the processing proceeds to step S4. When the processing proceeds to step S4, the control unit 15 determines whether a state in which the magnitude of the current value A falls within the predetermined range is maintained. For example, the control unit 15 is configured to compare the current value A input from the current detection unit 38 with a current threshold Th2 stored in the storage unit 15D of the control unit 15 and an upper limit current threshold Th3 that is greater than the current threshold Th2. For example, the control unit 15 is configured to be capable of determining, using its own timer function, whether a state in which the magnitude of the current value A is greater than or equal to the current threshold Th2 and smaller than the upper limit current threshold Th3 has continued for a predetermined time (i.e., whether fluctuations of the current flowing through the power path 11 have settled). In step S4, if the control unit 15 determines that the state in which the magnitude of the current value A is greater than or equal to the current threshold Th2 and smaller than he upper limit current threshold Th3 has not continued for the predetermined time (No in step S4), the processing of step S4 is repeated.

In step S4, if the control unit 15 determines that the state in which the magnitude of the current value A is greater than or equal to the current threshold Th2 and smaller than the upper limit current threshold Th3 has continued for the predetermined time (Yes in step S4), the processing proceeds to step S5. When the processing proceeds to step S5, the control unit 15 obtains, in the resistance value calculation unit 15A, the resistance value R based on the current values A and the voltage values V respectively input from the current detection unit 38 and the voltage detection unit 39. That is, the control unit 15 detects the resistance value R when the magnitude of the current value A flowing through the power path 11 is greater than or equal to the current threshold Th2. Then, the processing proceeds to step S6.

When the processing proceeds to step S6, the control unit 15 executes, in the degradation detection unit 15B, the degradation determination processing in which the resistance value R and the resistance threshold Th1 are compared. The control unit 15 executes the degradation determination processing in which the resistance value R when the switching control is executed by the control device C is compared with the resistance threshold Th1. For example, if it is determined, in the degradation determination processing, that the magnitude of the resistance value R is greater than or equal to the resistance threshold Th1 (Yes in step S6), the processing proceeds to step S7, in which the degradation signal Sd is output from the degradation detection unit 15B.

In contrast, if it is determined, in the degradation determination processing, that the magnitude of the resistance value R is smaller than the resistance threshold Th1 (No in step S6), the degradation signal Sd is not output. In this manner, the control unit 15 executes the degradation determination processing in which the resistance value R when the magnitude of the current flowing through the power path 11 is greater than or equal to the current threshold Th2 is compared with the resistance threshold Th1. In other words, the control unit 15 executes degradation determination processing in which the degree of degradation of the first switch 33A is determined by comparing the resistance threshold Th1 with the resistance value R of the first switch 33A that is based on the voltage value V (potential difference) corresponding to the potential difference between the two sides of the first switch 33A when the first switch 33A is in the ON state and current flows through the power path 11, and on the current value A flowing through the power path 11.

Next, when the degradation signal Sd is input to the notification function unit 15C, the notification function unit 15C performs information transmission to an external device (not shown). That is, the notification function unit 15C of the control unit 15 notifies an external entity of the degraded state. In this manner, the processing shown in FIG. 2 ends.

As the switching control by the control device C is repeatedly executed, the number of times of switching the first switch 33A to the ON state increases. This results in advancement of the wear and the oxidation of the contact in the first switch 33A, thus gradually increasing the resistance value R of the first switch 33A. The control unit 15 determines the degree of degradation of the first switch 33A by comparing the resistance threshold Th1 with the resistance value R that gradually increases with an increase in the number of times of switching to the ON state.

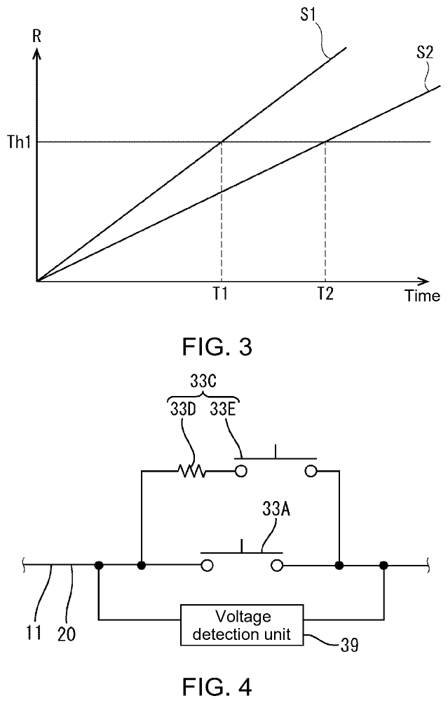

For example, when the frequency with which a large inrush current flows through the first switch 33A is high, the degree of temporal increase in the resistance value R of the first switch 33A is larger as indicated by a straight line S1 as shown in FIG. 3. In contrast, when the frequency with which a large inrush current flows through the first switch 33A is low, the degree of temporal increase of the resistance value R in the first switch 33A is smaller as indicated by a straight line S2. T1 denotes the time at which the magnitude of the resistance value R reaches the resistance threshold Th1 when the frequency with which a large inrush current flows through the first switch 33A is high (straight line S1), and T2 denotes the time at which the magnitude of the resistance value R reaches the resistance threshold Th1 when the frequency with which a large inrush current flows through the first switch 33A is low (straight line S2). Also, the time T1 is a timing earlier than the time T2.

Accordingly, when the frequency with which a large inrush current flows through the first switch 33A is high (straight line S1), the magnitude of the resistance value R reaches the resistance threshold Th1 earlier than when the frequency with which a large inrush current flows through the first switch 33A is low (straight line S2). That is, the cutoff device 1 according to the present disclosure determines the degree of degradation of the first switch 33A taking the state of the contact of the first switch 33A into account, thus allowing the first switch 33A to be operated in a form in which the durability performance thereof is enhanced.

Next, the effects of the present configuration will be illustrated.

A cutoff device 1 includes a first switch 33A configured to switch a power path 11 between a conductive state and a cutoff state, the power path 11 serving as a path to transmit power derived from a power supply unit 10. The cutoff device 1 includes a control unit 15 configured to execute degradation determination processing in which a resistance value R and a resistance threshold Th1 of the first switch 33A are compared. The control unit 15 determines that the first switch 33A is in a degraded state if the magnitude of the resistance value R is greater than or equal to the resistance threshold Th1, and notifies an external entity of the degraded state.

The cutoff device 1 may use the resistance value R of the first switch 33A as an indicator for estimating the state of the first switch 33A. This makes it possible to determine whether or not the first switch 33A is in the degraded state, in a form suitable for the first switch 33A itself, thus easily enhancing the durability performance of the first switch 33A. Furthermore, this configuration notifies an external entity of the degraded state, and therefore the external entity can easily take measures suitable for the state of the first switch 33A. Here, the degraded state refers to a state in which the first switch 33A has deteriorated as compared with the state thereof when initially provided in the cutoff device 1, and the performance thereof in switching the power path 11 between the conductive state and the cutoff state has been reduced.

In the cutoff device 1, the resistance value R is based on a potential difference between two sides of the first switch 33A when the first switch 33A is in an ON state and current flows through the power path 11, and on the current flowing through the power path 11. This configuration determines that the first switch 33A is in the degraded state if the resistance value R that is based on the potential difference between two sides of the first switch 33A when the first switch 33A is in the ON state and current flows through the power path 11, and on the current flowing through the power path 11 is greater than or equal to the resistance threshold Th1. This makes it possible to determine whether the first switch 33A is in the degraded state, in a form suitable for the state of the first switch 33A itself, and therefore the first switch 33A can be operated in a form in which the durability performance thereof is enhanced.

The cutoff device 1 further includes a second switch 33B configured to switch the power path 11 between the conductive state and the cutoff state. Start of energization or current increase of the power path 11 occurs as a result of execution of a switching control in which the first switch 33A is switched from an OFF state to the ON state after the second switch 33B. The control unit 15 executes the degradation determination processing in which the resistance value R when the switching control is executed is compared with the resistance threshold Th1.

In the switching control, the first switch 33A is switched to the ON state after the second switch 33B, and therefore an inrush current is likely to flow through the first switch 33A. Accordingly, the contact of the first switch 33A is susceptible to wear (degradation). With this configuration, the degradation of the first switch 33A can be determined in the switching control in which the contact of the first switch 33A is susceptible to wear.

In the cutoff device 1, the power path 11 includes a high-potential side power path 17, and a low-potential side power path 20 having a lower potential than the high-potential side power path 17. The second switch 33B is provided on the high-potential side power path 17, and the first switch 33A is provided on the low-potential side power path 20. The cutoff device 1 further includes a resistor 33D and a third switch 33E connected in series to the resistor 33D, and includes a parallel switching path 33C on which the resistor 33D and the third switch 33E are connected in parallel to the first switch 33A. The switching control is a control in which energization of the power path 11 is started by bringing the second switch 33B and the third switch 33E into the ON state while the first switch 33A is in the OFF state, and the first switch 33A is thereafter switched to the ON state while the second switch 33B and the third switch 33E are maintained in the ON state.

By starting energization of the power path 11 in advance by bringing the second switch 33B and the third switch 33E into the ON state, it is possible to cause current to flow through the power path 11 while suppressing an excessive increase in the peak of the current flowing through the third switch 33E by the resistor 33D. Thereafter, the first switch 33A is switched to the ON state while the second switch 33B and the third switch 33E are maintained in the ON state. Accordingly, it is possible to suppress the peak of the inrush current flowing through the first switch 33A.

In the cutoff device 1, the control unit 15 detects a voltage between two terminals of the first switch 33A. With this configuration, it is possible to more accurately detect the resistance value R of the first switch 33A of interest.

In the cutoff device 1, the control unit 15 executes degradation determination processing in which the resistance value R when the magnitude of the current flowing through the power path 11 is greater than or equal to a current threshold Th2 is compared with the resistance threshold Th1. The cutoff device 1 is configured to compare the current flowing through the power path 11 with the current threshold Th2, and it is therefore possible, for example, to narrow down the states of the current used for detecting the resistance value R to a state suitable for detection of the resistance value R, thus increasing the credibility of the calculated resistance value R.

### OTHER EMBODIMENTS

It should be appreciated that the embodiments disclosed herein are to be construed in all respects as illustrative and not limiting. The scope of the present disclosure is not limited to the embodiments disclosed herein, and is intended to include all modifications which fall within the scope of the claims and the meaning and scope of equivalents thereof.

Unlike Embodiment 1, the positions at which the voltage detection unit is connected may be any locations that can be regarded as having the same potential as the potentials of the terminals on two sides of the first switch. For example, as shown in FIG. 4, the voltage detection unit 39 may be connected to a position closer to the power supply unit side and a position closer to the load side than the position at which the parallel switching path 33C is electrically connected to the low-potential side power path 20.

Unlike Embodiment 1, the notification function unit may be formed as a display unit such as a lamp of a display device, and may be configured to perform notification through display. The notification function unit may be formed by an audio device such as a speaker, and may be configured to perform notification using audio.

Unlike Embodiment 1, the resistance value calculation unit, the degradation detection unit, and the notification function unit may be separately formed as individual information processing devices (individual microcomputers or the like).

Unlike Embodiment 1, the second switch may be provided on the low-potential side power path, and the first switch may be provided on the high-potential side power path. In this case, it is preferable that the parallel switching path is also provided on the high-potential side power path.

Unlike Embodiment 1, the control unit and the control device may be formed as a single microcomputer.

Unlike Embodiment 1, the degradation determination processing may be executed after determining that the rate of increase of the current of the power path is less than or equal to a certain value. For example, an amount of change Ki per unit time of the current of the power path is determined by Expression 1 below. Ki=|A1−A2|/Δ T . . . (Expression 1), where A1 is the current value A1 currently detected by the current detection unit, A2 is the current value A2 previously detected by the current detection unit, and ΔT is a periodicity ΔT of time in which the current detection unit repeatedly detects the current value. The current value A2 may be stored in the RAM of the control unit, for example. The amount of change Ki is a value obtained by dividing the absolute value of the difference between the current value A1 and the current value A2 by the periodicity ΔT. For example, it may be determined that the fluctuations in the current flowing through the power path have settled if a state in which the amount of change Ki is smaller than the threshold stored in the storage unit of the control unit has continued for a predetermined time, and the resistance value of the first switch thereafter may be calculated.

Unlike Embodiment 1, it is possible to adopt a configuration in which the third switch is not provided. In this case, execution of the switching control will cause current increase in which the current value flowing through the power path rapidly increases.

Unlike Embodiment 1, it is possible to adopt a configuration in which table data in which resistance values corresponding to current values and voltage values are defined is stored in advance in the storage unit, and the resistance values corresponding to the current values and the voltage values are used from the table data.

Unlike Embodiment 1, it is possible to adopt a configuration in which table data in which resistance values of each of the switches that correspond to the number of times of opening/closing of the switch are defined is stored in advance in the storage unit, and the resistance values corresponding to the number of times of opening/closing of the switch are used from the table data.

The maximum value of an inrush current of a switch is considered to decrease with an increase in the resistance value of the switch. Accordingly, unlike Embodiment 1, it is possible to adopt a configuration in which table data in which a resistance value of each of the switches that correspond to the maximum value of the inrush current of the switch is defined is stored in advance in the storage unit, and the resistance value corresponding to the maximum value of the inrush current of the switch is used from the table data.

1. A vehicle cutoff device comprising a switch configured to switch a power path between a conductive state and a cutoff state, the power path serving as a path to transmit power from a power supply unit, wherein
the cutoff device comprises a control unit configured to execute degradation determination processing in which a resistance value and a resistance threshold of the switch are compared,
the resistance value is based on a potential difference between two sides of the switch when the switch is in an ON state and current flows through the power path, and on the current flowing through the power path, and
the control unit calculates the resistance value and executes the degradation determination processing when a state in which a magnitude of the current flowing through the power path is within a range greater than or equal to a current threshold and smaller than an upper limit current threshold has continued for a predetermined time, and determines that the switch is in a degraded state when the resistance value is greater than or equal to the current threshold, and notifies an external entity of the degraded state.

2. (canceled)

3. The vehicle cutoff device according to claim 1, further comprising
a second switch configured to switch the power path between the conductive state and the cutoff state, wherein
start of energization or current increase of the power path occurs as a result of execution of a switching control in which the switch is switched from an OFF state to the ON state after the second switch, and
the control unit executes the degradation determination processing in which the resistance value when the switching control is executed is compared with the resistance threshold.

4. The vehicle cutoff device according to claim 3, wherein
the power path includes a high-potential side power path, and a low-potential side power path having a lower potential than the high-potential side power path,
the second switch is provided on one of the high-potential side power path and the low-potential side power path, and the switch is provided on the other of the high-potential side power path and the low-potential side power path,
the cutoff device further comprises a resistor, and a third switch connected in series to the resistor, and includes a parallel switching path on which the resistor and the third switch are connected in parallel to the switch, and
the switching control is a control in which energization of the power path is started by bringing the second switch and the third switch into the ON state while the switch is in the OFF state, and the switch is thereafter switched to the ON state while the second switch is maintained in the ON state.

5. The vehicle cutoff device according to claim 4, wherein the control unit detects a voltage between two terminals of the switch.

6. (canceled)
